(19) United States
(12) Patent Application Publication
(10) Pub. No.: US 2014/0291822 A1
(43) Pub. Date: Oct. 2, 2014

(54) INTEGRATED CIRCUIT PACKAGE

(71) Applicant: TEXAS INSTRUMENTS INCORPORATED, Dallas, TX (US)

(72) Inventor: Lim Jin Keong, Wangsa Maju (MY)

(73) Assignee: Texas Instruments incorporated, Dallas, TX (US)

(21) Appl. No.: 13/853,776

(22) Filed: Mar. 29, 2013

(51) Int. Cl. H01L 21/82; H01L 23/495

(52) U.S. Cl. CPC H01L 21/82; H01L 23/495
USPC 257/666; 438/112

(57) ABSTRACT

An integrated circuit (“IC”) package including an IC assembly mounted on a leadframe and an encapsulant block covering the IC assembly and portions of the leadframe. The encapsulant block has a molded chamfered outer surface portion and the leadframe has a saw cut outer periphery.

### BACKGROUND

Integrated circuit packages, such as QFN (quad-flat no-leads) physically and electrically connect integrated circuits (“IC's”) to printed circuit boards (“PCB's”) or other electronic components. A QFN package is a plastic encapsulated package made with a planar copper lead frame substrate. Perimeter lands on the package bottom provide electrical connections between an IC assembly in the package and a PCB on which the package is mounted. Flat no-lead packages include an exposed thermal pad to improve heat transfer out of the IC assembly into the PCB.

Some IC packages include only a leadframe, an IC die mounted on the leadframe and a layer of encapsulant that covers the die and part of the leadframe. Other IC packages include one or more dies and one or more discrete components such as resistors, capacitors and inductors, which are mounted directly or indirectly on the leadframe and which are covered by a layer of encapsulant. An IC package containing several components is sometimes referred to as a “systems package.” When the components in a systems package are stacked on top one another the package is sometimes referred to as a “3D package.” In this specification the phrase “IC package” is used to refer simple IC packages as well as systems packages and 3D packages. The phrase “IC assembly” is used to refer to the IC die and any other electrical components that may be part of a particular IC package, thus a single die or a vertically stacked group of die(s) with passive component(s) that are attached to an IC package substrate is referred to herein as an “IC assembly.”

### BRIEF DESCRIPTION OF THE DRAWINGS

FIG. 1 is a side elevation view of an integrated circuit (“IC”) assembly.

FIG. 2 is an isometric top view of the IC assembly of FIG. 1.

FIG. 3 is an isometric bottom view of the IC assembly of FIGS. 1 and 2.

FIG. 4 is a cross sectional view of a conventional IC package.

FIG. 5 is a isometric top view of the IC package of FIG. 4.

FIG. 6 is an isometric bottom view of the IC package of FIG. 4.

FIG. 7 is a cross sectional view of an improved IC package.

FIG. 8 is an isometric top view of the improved IC package of FIG. 7.

FIG. 9 is an isometric bottom view of the improved IC package of FIGS. 7 and 8.

FIG. 10 is a top plan view of a portion of a multi-cavity mold.

FIG. 11 is an isometric bottom view of a portion of a multi-cavity mold.

FIG. 12 is a detail bottom isometric view of a mold cavity of the multi-cavity mold of FIGS. 10 and 11.

FIG. 13 is a schematic side elevation view of a leadframe strip assembly.

FIG. 14 is a schematic top plan view of a molded leadframe strip assembly.

FIG. 15 is a schematic elevation view of the molded leadframe strip assembly of FIG. 14 showing a saw singulation operation performed thereon.

FIG. 16 is a detail cross sectional elevation view of an improved IC package.

FIG. 17 is a flow chart of one embodiment of a method of making an integrated circuit package.

FIG. 18 is a flow chart of another embodiment of a method of making an integrated circuit package.

### DETAILED DESCRIPTION

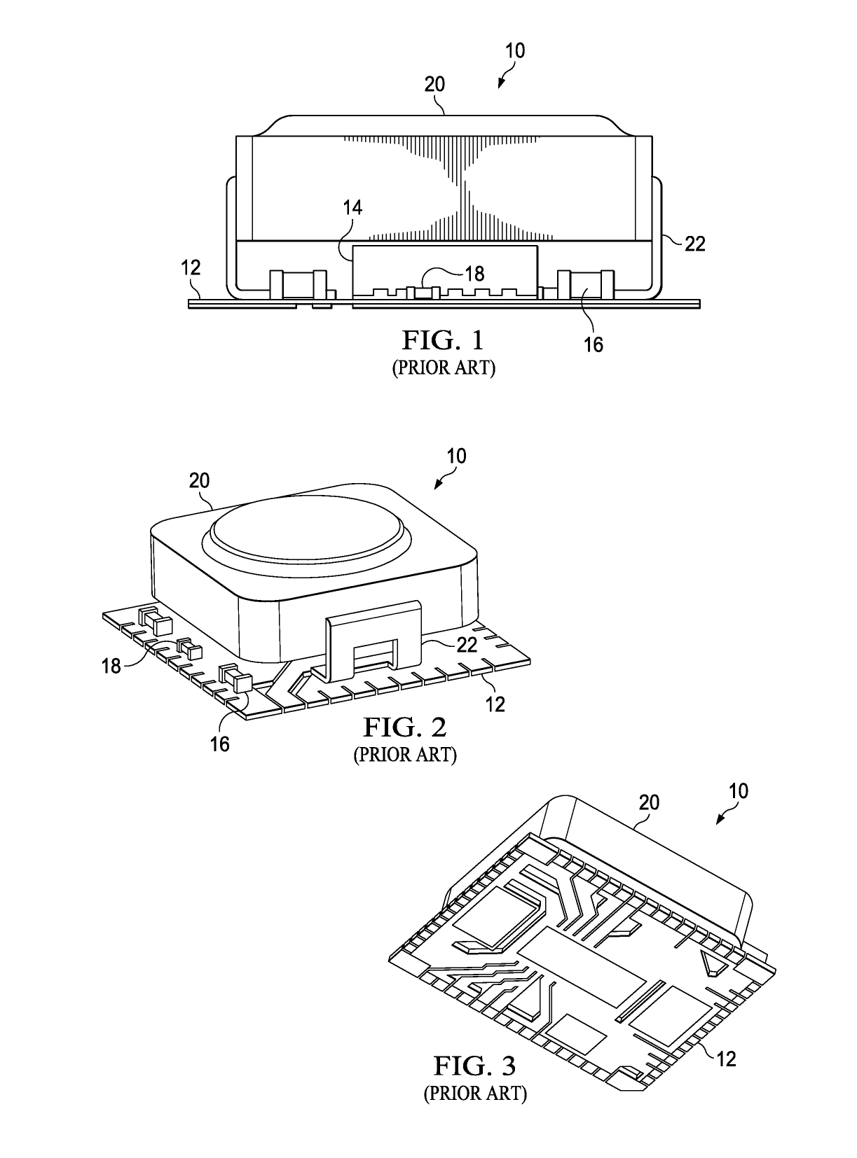

FIGS. 1-3 illustrate an IC assembly 10 mounted on a leadframe 12. The components of the IC assembly 10 include an IC die 14 and multiple passive circuit components including capacitors 16, resistors 18, and an inductor 20. The inductor 20 is physically mounted on the die 14, as by solder, and is connected to the substrate 12 by stilted terminals. Such 3D IC assemblies pose particular challenges to IC package designers, as will be discussed below.

The terms “top” and “bottom” as used herein do not imply any particular orientation With respect to a gravitational field, but rather are used in a relative sense for describing the spatial relationship between various objects, often based upon the orientation of a drawing figure. The terms “up,” “down,” “upper,” “lower,” “vertical,” “horizontal” and similar terms are used in the same manner. When describing IC assemblies, such as IC assembly 10, the assembly is usually described with the substrate, e.g. substrate 12, positioned at the bottom rather than the top. Again, since “top” and “bottom” are used in a relative sense, the description of the IC assembly 10 that is provided herein is accurate no matter how the IC assembly may be oriented in space, top up, top down or lying on its side.

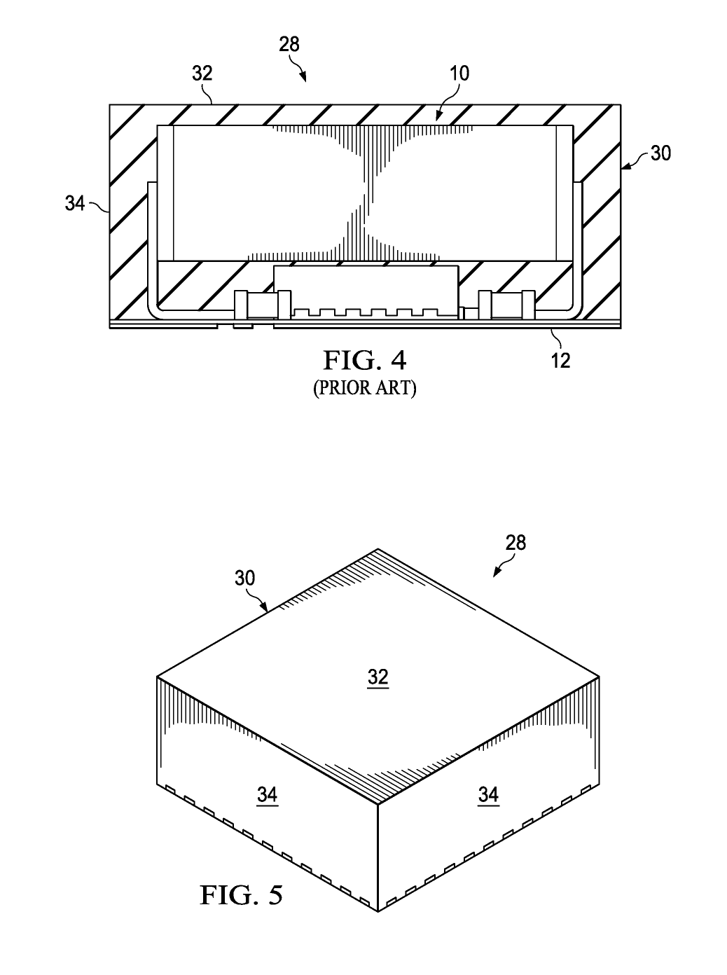

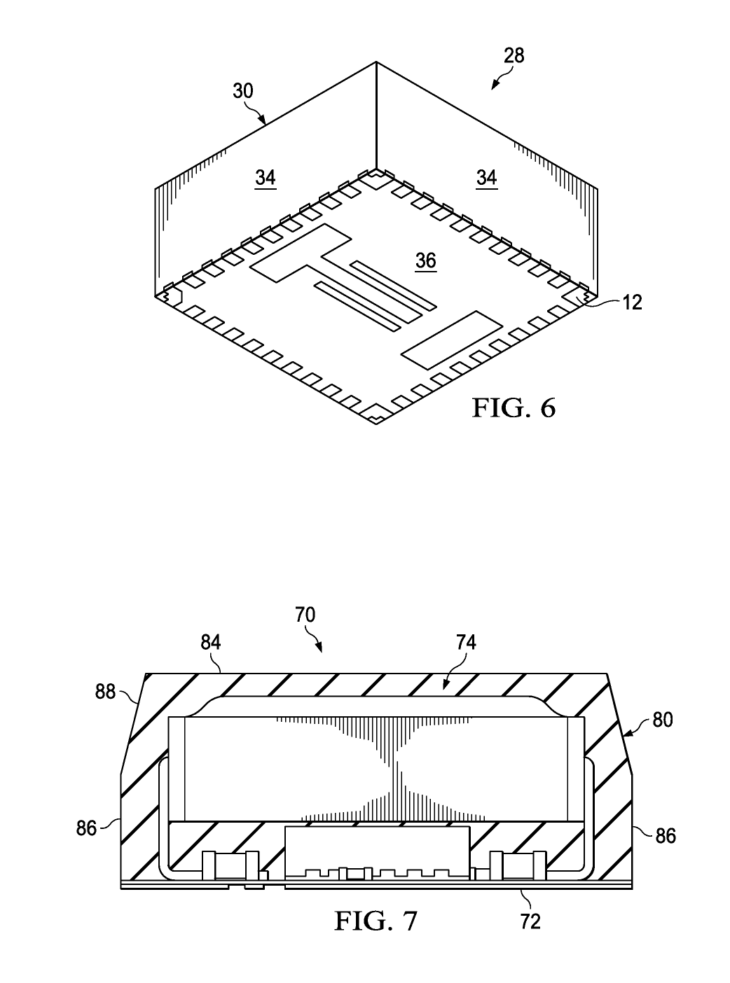

A conventional IC package 28 that includes the IC assembly 10 of FIGS. 1-3 is illustrated in FIGS. 4-6. The IC package 28 includes a regular parallelepiped shaped (rectangular box shaped) encapsulant block 30 that has a flat top wall 32 and a generally flat bottom wall 36 on which portions of the leadframe 12 are exposed. Four generally flat sidewalls 34 extend between the top and bottom walls 32, 36 and are generally perpendicular to both. Edge surface portions of the leadframe 12 are exposed at a lower portion of each sidewall 34 and provide lands for connecting the IC assembly 10 to a printed circuit board. Such box shaped IC packages 28 are conventionally formed by block molding and saw singulating. At the beginning of the IC package 28 forming process, an IC assemblies 10 is attached to each leadframe 12 of a leadframe strip (not shown) having a plurality of integrally connected leadframes 12. During molding the leadframe strip and attached IC assemblies 10 are mounted in a single cavity mold (not shown). Molten mold compound is forced under pressure into the single mold cavity. The mold compound flows around and in between the IC assemblies 10 and then cools and cures into a single solid encapsulant block. Each of the IC assemblies 10 is sealed within this single large block of solidified mold compound. Next the block is “singulated” by sawing it into multiple small units that each provide an IC package 28.

One problem with IC packages for relatively tall IC assemblies, such as the 3D IC assembly 10, is that standard singulation saw blades tend to overheat and break because of the greater thickness of encapsulant that must be cut. Also, the saw blades sometimes warp slightly when sawing this greater thickness of encapsulant resulting in nonlinear cuts.

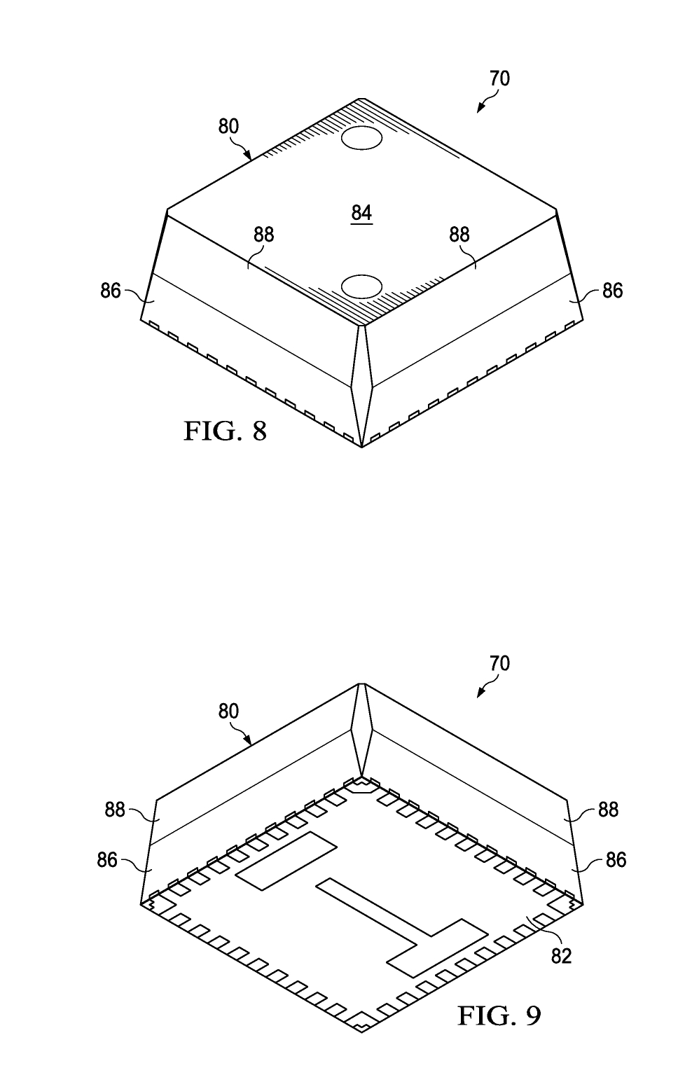

An improved IC package 70 is illustrated in FIGS. 7-9. The IC package 70 has a leadframe 72 that may be similar or identical to the leadframe 12 described above. An IC assembly 74, which may be similar or identical to the IC assembly 10, is mounted on the leadframe 12. The IC assembly 74 and a portion of the leadframe 72 are encapsulated in a layer 80 of protective encapsulant, which is usually referred to herein as an encapsulant block 80. Encapsulant block 80 may be an epoxy encapsulant or other conventional encapsulant. The encapsulant block 80 may have a generally flat, rectangular bottom wall, through which a portion of the leadframe 72 is exposed. The encapsulant block 80 may have a generally flat top wall 84. The encapsulant block 80 has a plurality of fiat lower sidewall portions 86 that extend substantially perpendicular to the substrate 72 and to top wall 84. The encapsulant block 80 has a plurality of flat, chamfered upper sidewall portions 88 that extend between the flat lower sidewall portions 86 and the top wall 84. The flat chamfered upper sidewall portions 88 are inclined outwardly and downwardly from the top wall 84. In one embodiment the angle “a” between the top wall 84 and the chamfered upper wall portion 88 is in a range of between about 10° and 15°. In one embodiment, angle “a” is about 13°. In one specific embodiment the encapsulant block 80 base may be about 10 mm×10 mm and the height may be about 4.3 mm. In another specific embodiment the base may be shout 15 mm×16 mm and the height may be about 5.8 mm. In another specific embodiment the base may be about 8 mm×8 mm and the height may be about 4.3 mm.

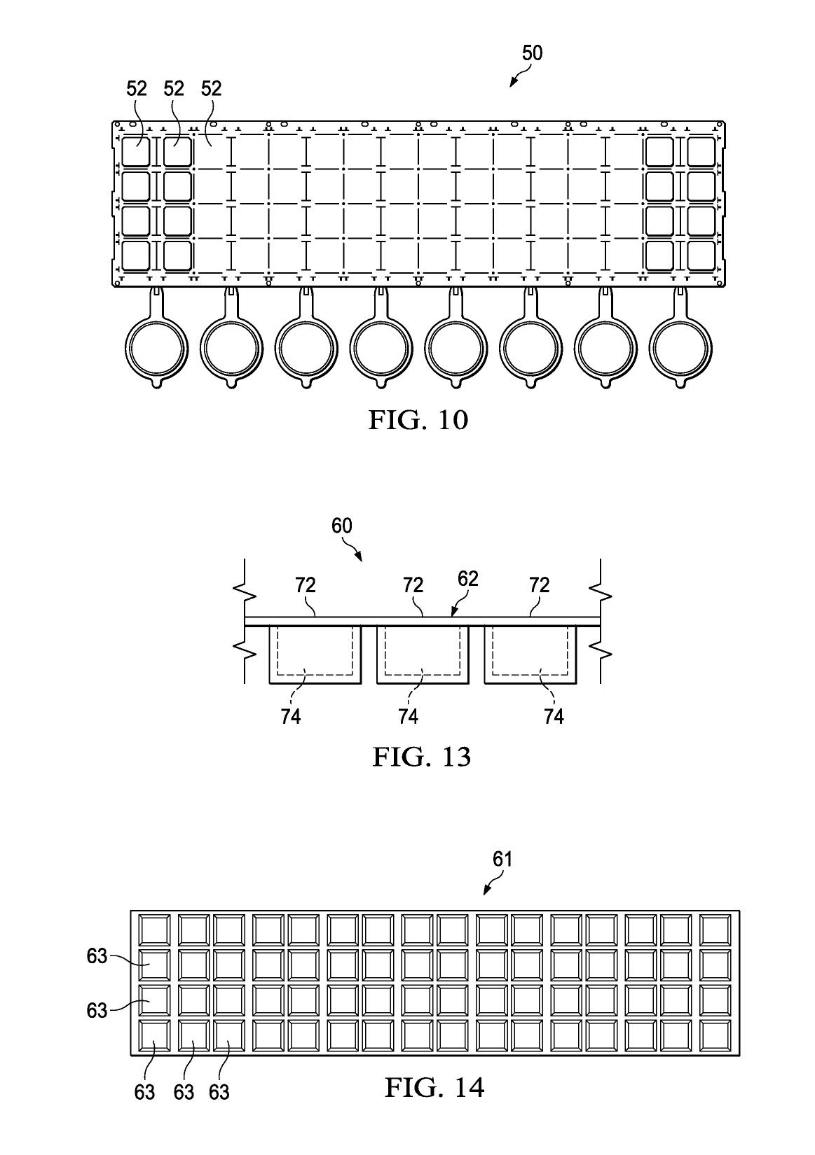

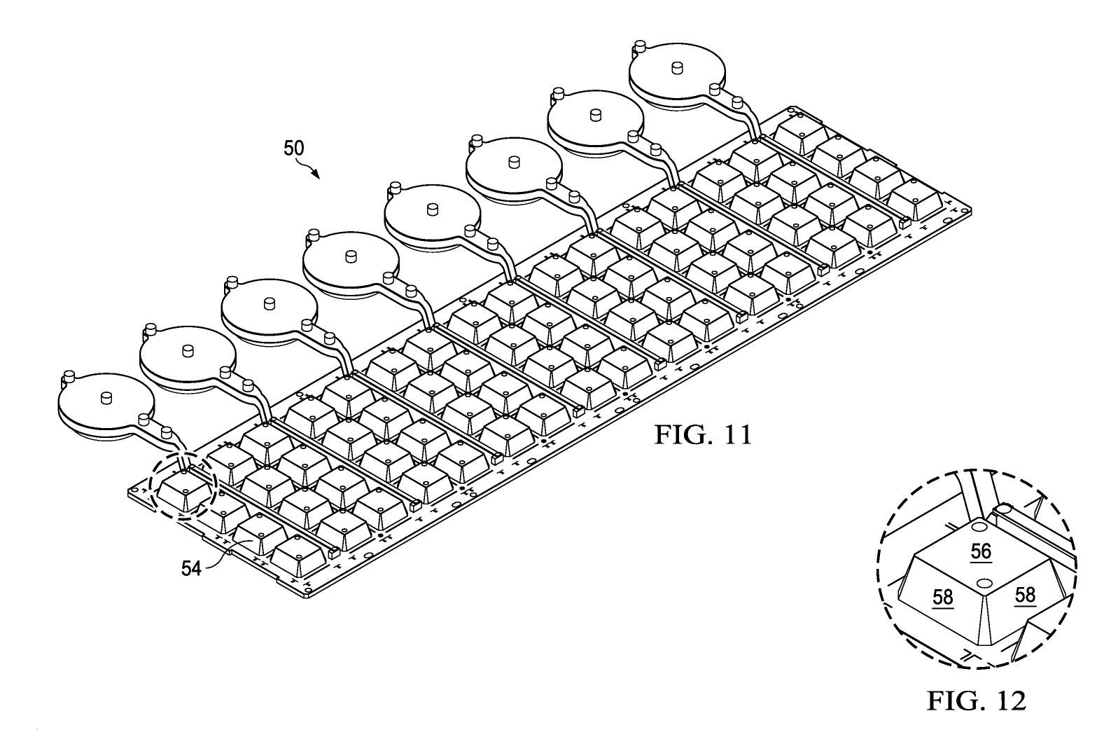

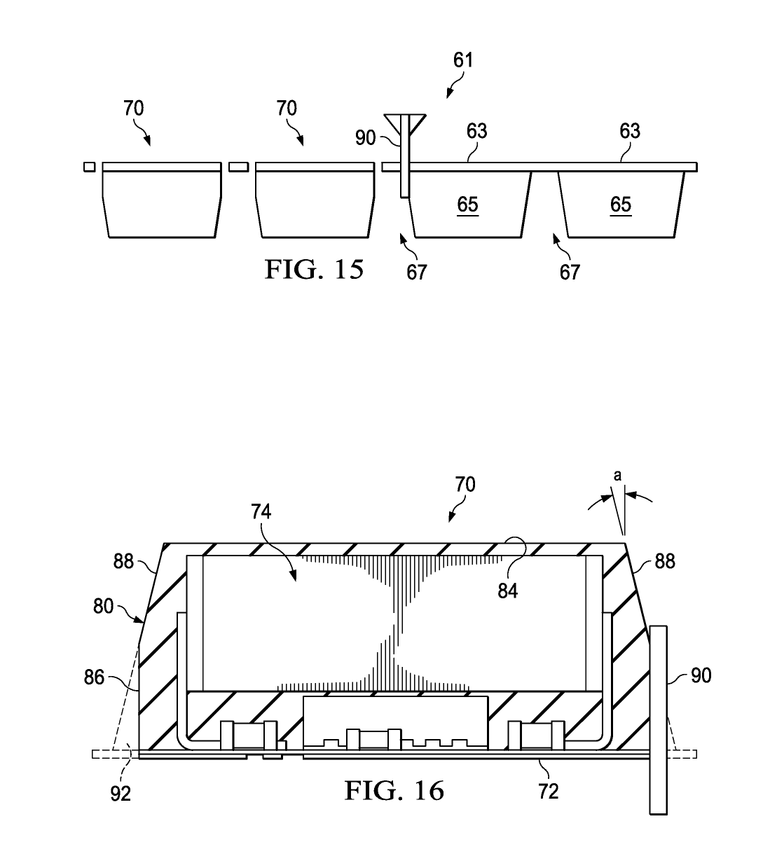

FIGS. 10-12 illustrate a multi-cavity mold 50 which may be used to produce improved IC packages 70. The multi-cavity mold 50 has a plurality of individual, spaced apart mold cavities 52, each adapted to receive only one IC assembly 74. Each of the mold cavities 52 is defined by a generally flat bottom wall 56 and a plurality of chamfered sidewalls 58, as best shown in FIG. 12. IC assemblies 72 may be conventionally formed on leadframes 72 that are integrally connected in a leadframe strip 62, as illustrated schematically in FIG. 13. The leadframe strip 62 is positioned, as illustrated in FIG. 13, with the IC assemblies 74 extending downwardly from the leadframes 72. The leadframe strip 62 is moved above the multi-cavity die 50 and moved downwardly so as to place one IC assembly 74 in each cavity 52. The multi-cavity die 50 is then closed and molten mold compound is forced into each cavity under pressure. After cooling and curing a newly formed “molded leadframe strip assembly” 61, FIGS. 14 and 15, is removed from the multi-cavity die 50 and transferred to a sawing station.

As illustrated by FIGS. 14 and 15, the molded leadframe strip assembly 61 comprises integrally connected, now partially encapsulated leadframes 63, with a molded IC assembly 65 extending downwardly from each leadframe 63, FIG. 15. The molded IC assemblies 65 are separated by generally trapezoid shaped voids 67. As shown schematically by FIG. 15, at the sawing station a circular saw blade 90 is used to make a plurality of single depth cuts through the leadframe strip 62 to separate the leadframes 72 with attached molded IC assemblies 65 to provide a plurality of separate IC packages 70. Each separation of two adjacent leadframes 63 requires two cuts, one for each leadframe 63. As best illustrated in FIGS. 15 and 16, in one embodiment each cut is made at a position aligned with a portion of the trapezoid shaped void 67, such that, after the cut is made, each sidewall surface of the encapsulant block 80 comprises one portion 86 that was made by the cut of saw blade 90 and one portion 88 that was formed by contact with a wall of a mold cavity 52. A peripheral portion of the leadframe that provides the package lands also has a cut surface formed by the saw blade 90. One advantage of this method of package formation is that an IC package 70 is formed that has a relatively small upper periphery compared to a package for the same or similar configuration is that the total footprint of the IC package 70 is considerably smaller at its upper periphery that a prior art saw cut package 30, FIGS. 4-6, that packages an IC assembly 10 identical to the IC assembly 74 of the package 70. Also, because of the vertical saw cuts, the bottom portion of the package 70 has a smaller perimeter than that a package with the same IC assembly 74 would have if it were formed with a punch (not shown) and provided with the same draft angle “a” at the top of the package. This may be appreciated from the dotted border portion 92, which shows the material removed from the package 70, in FIG. 16. Also, since the blade 90 cuts through only a portion (about half in FIG. 16) of the total height of the encapsulant block 80, problems of blade overheating and warping, such as experienced with conventional saw singulated packages, are obviated.

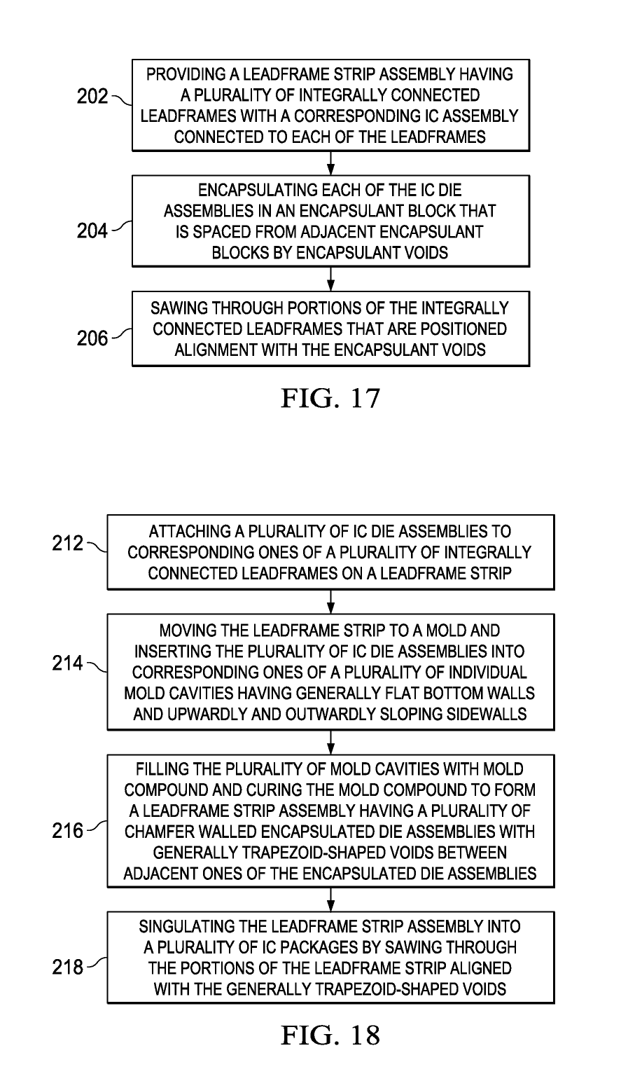

As illustrated by FIG. 17, one embodiment of a method of making an integrated circuit (“IC”) package includes, as shown at 202, providing a leadframe strip assembly having a plurality of integrally connected leadframes with a corresponding IC assembly connected to each of the leadframes. The method also includes, as shown at 204, encapsulating each of the IC die assemblies in an encapsulant block that is spaced from adjacent encapsulant blocks by encapsulant voids. The method further includes, as shown at 206, sawing through portions of the integrally connected leadframes that are positioned in alignment with the encapsulant voids.

FIG. 18 illustrates another embodiment of a method of making an integrated circuit package. The method includes, as shown at 212, attaching a plurality of IC die assemblies to corresponding ones of a plurality of integrally connected leadframes on a leadframe strip; and, as shown at 214, moving the leadframe strip to a mold and inserting the plurality of if die assemblies into corresponding ones of a plurality of individual mold cavities having generally flat bottom walls and upwardly and outwardly sloping sidewalls. The method also includes, as shown at 216, filling the plurality of mold cavities with mold compound and curing the mold compound to form a leadframe strip assembly having a plurality of chamfer walled encapsulated die assemblies with generally trapezoid shaped spaces between adjacent ones of the encapsulated die assemblies. The method further includes, as shown at 218, singulating the leadframe strip assembly into a plurality of IC packages by sawing through the portions of the leadframe strip aligned with the generally trapezoid shaped voids.

While certain specific embodiments of an integrated circuit package and a production methodology have been described in detail herein, various alternative embodiments will be obvious to those skilled in the art after reading this disclosure. It is intended that the appended claims be broadly construed so as to cover all such alternative embodiments, except as limited by the prior art.

1. A method of making an integrated circuit (“IC”) package comprising:
providing a leadframe strip assembly having a plurality of integrally connected leadframes with a corresponding IC assembly connected to each of the leadframes;
encapsulating each of the IC die assemblies in an encapsulant block that is spaced from adjacent encapsulant blocks by encapsulant voids; and
sawing through portions of the integrally connected leadframes that are positioned in alignment with the encapsulant voids.

2. The method of claim 2 wherein said encapsulating comprises positioning each IC assembly in a separate mold cavity of a multi-cavity mold.

3. The method of claim 2 wherein said positioning comprises positioning each IC assembly in a separate mold cavity having chamfered side walls.

4. The method of claim 2 wherein said positioning comprises positioning each IC assembly in a separate mold cavity having chamfered side walls extending upwardly and outwardly from a bottom wall.

5. The method of claim 1 wherein said encapsulating comprises encapsulating each of the IC die assemblies in an encapsulant block that is spaced from adjacent encapsulant blocks by generally V-shaped encapsulant voids.

6. The method of claim 1 wherein said sawing comprises sawing through portions of the integrally connected leadframes that are positioned in alignment with the encapsulant voids with a saw blade that extends into each of the encapsulant voids during the sawing.

7. The method of claim 1 wherein said sawing comprises sawing through portions of the integrally connected leadframes that are positioned in alignment with the encapsulant voids with a saw blade that extends through a portion of each of the encapsulant blocks and into each of the encapsulant voids during the sawing.

9. The method of claim 1 wherein said sawing comprises sawing in a direction normal to the integrally connected leadframes.

10. The method of claim 4 wherein said positioning comprises positioning each IC assembly in a separate mold cavity having chamfered side walls extending upwardly and outwardly from a bottom wall at an angle of about 103° with the bottom wall.

11. A method of making an integrated circuit (“IC”) package comprising:
attaching a plurality of IC die assemblies to corresponding ones of a plurality of integrally connected leadframes on a leadframe strip;
moving the leadframe strip to a mold and inserting the plurality of IC die assemblies into corresponding ones of a plurality of individual mold cavities having generally flat bottom walls and upwardly and outwardly sloping sidewalls;
filling the plurality of mold cavities with mold compound and curing the mold compound to form a leadframe strip assembly having a plurality of chamfer walled encapsulated die assemblies with generally trapezoid-shapedspaces between adjacent ones of the encapsulated die assemblies;
singulating the leadframe strip assembly into a plurality of IC packages by sawing through the portions of the leadframe strip aligned with the generally trapezoid-shaped spaces.

12. The method of claim 11 wherein said singulating comprises sawing through the portions of the leadframe strip aligned with the generally trapezoid-shaped spaces and through portions of the chamfered wall of the chamfer walled encapsulated die assemblies to provide a plurality of IC packages having a generally flat base portion, a first peripheral wall portion extending from the flat base portion and generally perpendicular thereto and a second peripheral wall portion extending from the first peripheral wall portion and inclined inwardly relative thereto.

13. An integrated circuit (“IC”) package comprising:
an IC assembly mounted on a leadframe;
an encapsulant block covering the IC assembly and portions of the leadframe;
said encapsulant block comprising a molded chamfered outer surface portion; and
said leadframe comprising a saw cut outer periphery.

14. The IC package of claim 13 wherein said encapsulant block comprises a saw cut outer surface portion.

15. The IC package of claim 14 wherein said saw cut outer surface portion is positioned between said molded chamfered outer surface portion and said saw cut outer periphery of said leadframe.

16. The IC package of claim 15 wherein said molded chamfered outer surface portion slopes inwardly relative to a plane perpendicular to said leadframe at an angle of between about 10° and 20°.

17. The IC package of claim 15 wherein said molded chamfered outer surface portion slopes inwardly relative to a plane perpendicular to said leadframe at an angle of about 13°.

18. The IC package of claim 17 wherein said saw cut outer surface portion extends generally perpendicular to said leadframe.

19. The IC package of claim 14 wherein said saw cut outer surface portion extends generally perpendicular to said leadframe.

20. The IC package of claim 14:
wherein said sawcut outer surface of said encapsulant block has a first height;
wherein said molded chamfered outer surface of said encapsulant block portion has a second height; and
wherein said first height and said second height are about the same.
